(19) United States
(12) Patent Application Publication
(10) Pub. No.: US 2007/0284643 A1
(43) Pub. Date: Dec. 13, 2007

(54) Capacitor structure of semiconductor memory and method for preparing the same

(75) Inventor: Hsiao Che Wu, Jhongli City (TW)

Correspondence Address: OLIFF & BERRIDGE, PLC, P.O. BOX 19928, ALEXANDRIA, VA, 22320, US

(73) Assignee: PROMOS TECHNOLOGIES INC., Hsinchu (TW)

(21) Appl. No.: 11/498,716

(22) Filed: Aug. 4, 2006

(30) Foreign Application Priority Data
Jun. 7, 2006 (TW) 095120136

(51) Int. Cl. H01L 29/00; H01L 21/00; H01L 27/108; H01L 21/8242

(52) U.S. Cl. 257/309; 438/396; 438/253; 257/534

(57) ABSTRACT

A capacitor structure comprises a plurality of cylinders and a supporting ring positioned among the plurality of cylinders and connecting a portion of the sidewall of each cylinder. The cylinders can be hollow circular cylinders, and the supporting ring can be positioned on a top portion of the cylinders. The capacitor structure may comprise a plurality of supporting rings and a hard mask separating these supporting rings from each other. The supporting rings and the hard mask are made of different material; for example, the supporting rings can be made of silicon oxide or aluminum oxide, and the hard mask can be made of silicon oxide or polysilicon. The capacitor structure comprises a first electrode positioned in the hollow circular cylinder, a dielectric layer positioned on the surface of the first electrode and a second electrode positioned on the surface of the dielectric layer.

### BACKGROUND OF THE INVENTION

(A) Field of the Invention

The present invention relates to a capacitor structure of a semiconductor memory and a method for preparing the same, and more particularly, to a capacitor structure of a semiconductor memory and a method for preparing the same, which is suitable for application to high integrity fabrication processes.

(B) Description of the Related Art

A memory cell of the DRAM generally consists of a metal oxide semiconductor field effect transistor (MOSFET) and a capacitor, and the transistor includes a source electrode electrically connected to a bottom electrode of the capacitor. There are two types of capacitors: stacked capacitors and deep trench capacitors. The stacked capacitor is fabricated on the surface of a silicon substrate, while the deep trench capacitor is fabricated inside the silicon substrate.

FIG. 1 and FIG. 2 illustrate a method for preparing a stacked capacitor 22 according to the prior art. The method forms a semicrown-shaped bottom electrode 20′, and a dielectric layer 24 is then formed on the semicrown-shaped bottom electrode 20′, wherein the semicrown-shaped bottom electrode 20′ is hollow. Subsequently, an upper electrode 26 is formed on the dielectric layer 24 to complete the stacked capacitor 22. The integrity of the dynamic random access memory increases rapidly with continuous improvements in the semiconductor fabrication process, but the lateral width of the capacitor must be decreased to achieve the high integrity. However, decreasing the lateral width results in reduced size of the surface area, i.e., a reduced capacitance, which is proportional to the surface area.

To maintain or increase the capacitance of the capacitor, researchers increase the vertical height and decrease the lateral width of the capacitor to increase the size of the surface area of the capacitor, i.e., increase the aspect ratio of the capacitor in response to the decreased lateral width of the capacitor for achieving high integrity. However, achieving the objective of high integrity by increasing the aspect ratio of the capacitor creates an arduous problem, i.e., the hollow semicrown-shaped bottom electrode 20′, referring to FIG. 1, is likely to lean or even collapse due to insufficient mechanical supporting strength during the fabrication process.

To solve the problem of insufficient mechanical supporting strength, D. H. Kim et al. disclose a method for preparing a mechanical strength enhanced storage node (see “A mechanically enhanced storage node for virtually unlimited height (MESH) capacitor aiming at sub 70 nm DRAMs”, IEDM, 04, p 69-72). In particular, the method disclosed by D. H. Kim et al. uses a network structure made of silicon nitride to enhance the mechanical supporting strength.

### SUMMARY OF THE INVENTION

One object of the present invention provides a capacitor structure of a semiconductor memory and a method for preparing the same, which uses a supporting ring connecting a plurality of cylinders to enhance the mechanical supporting strength to prevent the cylinders from leaning or collapsing during the fabrication process of the capacitor structure due to insufficient mechanical supporting strength, and therefore is applicable to high integrity fabrication processes.

A capacitor structure of a semiconductor memory according to this aspect of the present invention comprises a plurality of cylinders having an outer sidewall and at least one supporting ring positioned between the cylinders and connecting portions of the outer sidewalls of the cylinders. The supporting ring may connect an upper portion of the cylinders, and the cylinders are hollow cylinders. The capacitor structure may further comprise a plurality of disconnected supporting rings and a hard mask isolating the supporting rings. The supporting ring and the hard mask may be made of different materials, for example, the supporting ring may include aluminum oxide or silicon nitride, and the hard mask may include silicon oxide or polysilicon. The capacitor structure comprises a first electrode included in the hollow cylinder, a dielectric layer positioned on the surface of the first electrode; and a second electrode positioned on the surface of the dielectric layer.

Another aspect of the present invention provides a method for preparing a capacitor structure of a semiconductor memory, in which a plurality of solid cylinders are formed in a stack structure, and each solid cylinder has a top end higher than a top end of the stack structure. A hard mask having a plurality of first openings is then formed on the stack structure, and each first opening exposes a portion of the stack structure and a portion of an outer sidewall of the solid cylinder. Subsequently, a supporting ring is formed in the first opening of the hard mask, and the supporting ring connects a portion of the outer sidewall of the solid cylinders. Forming the supporting ring in the first opening of the hard mask comprises forming a supporting layer covering the stack structure, the solid cylinders and the hard mask, and performing an anisotropic etching process to remove a portion of the supporting layer such that the supporting layer remaining in the first opening forms the supporting ring.

Preferably, forming a hard mask having a plurality of first openings on the stack structure forms a mask layer on the stack structure and the solid cylinders, and an anisotropic etching process is then performed to remove a portion of the mask layer from the stack structure to form a second opening exposing the stack structure. Subsequently, an isotropic etching process is performed to remove a portion of the mask layer from the stack structure to enlarge the second opening to be in contact with the outer sidewall of the solid cylinders to form the hard mask.

The conventional hollow semicrown-shaped bottom electrode is likely to lean or even collapse due to insufficient mechanical supporting strength during the fabrication process. In contrast, the capacitor structure of the present invention possesses a supporting ring positioned between the cylinders and connecting a portion of the outer sidewall of the cylinders such that the cylinders provide mechanical support to each other through the connection of the supporting ring. Consequently, the capacitor structure will not lean or collapse during the subsequent fabrication process, and the method of the present invention is suitable for application to the high integrity fabrication process.

### BRIEF DESCRIPTION OF THE DRAWINGS

The objectives and advantages of the present invention will become apparent upon reading the following description and upon reference to the accompanying drawings in which:

FIG. 1 and FIG. 2 illustrate a method for preparing a stacked capacitor according to the prior art;

FIG. 3 to FIG. 12 illustrate a method for preparing a capacitor structure of a semiconductor memory according to the first embodiment of the present invention;

FIG. 13 to FIG. 18 illustrate a method for preparing a capacitor structure of a semiconductor memory according to the second embodiment of the present invention; and

FIG. 19 to FIG. 26 illustrate a method for preparing a capacitor structure of a semiconductor memory according to the third embodiment of the present invention.

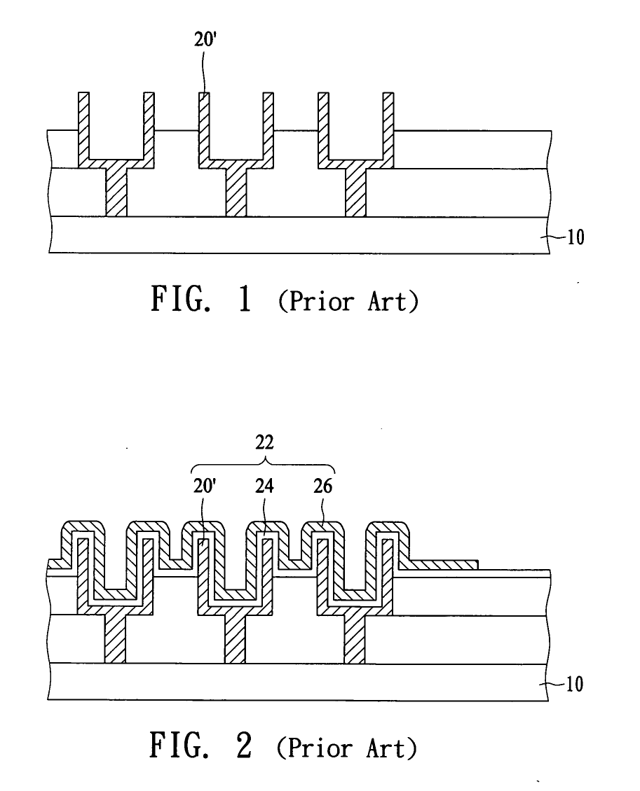

### DETAILED DESCRIPTION OF THE INVENTION

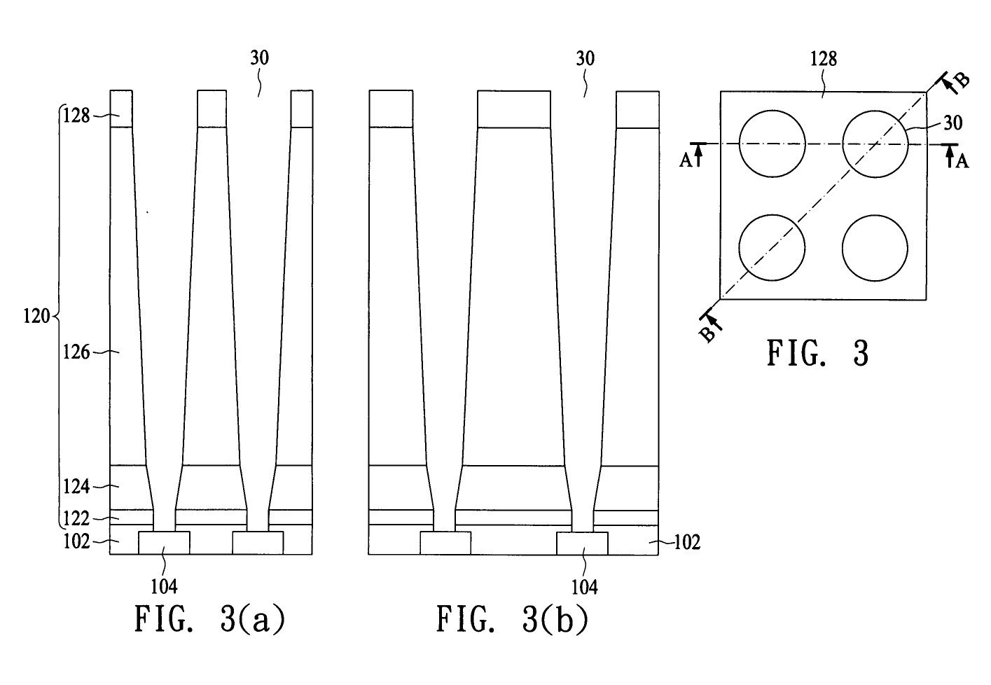

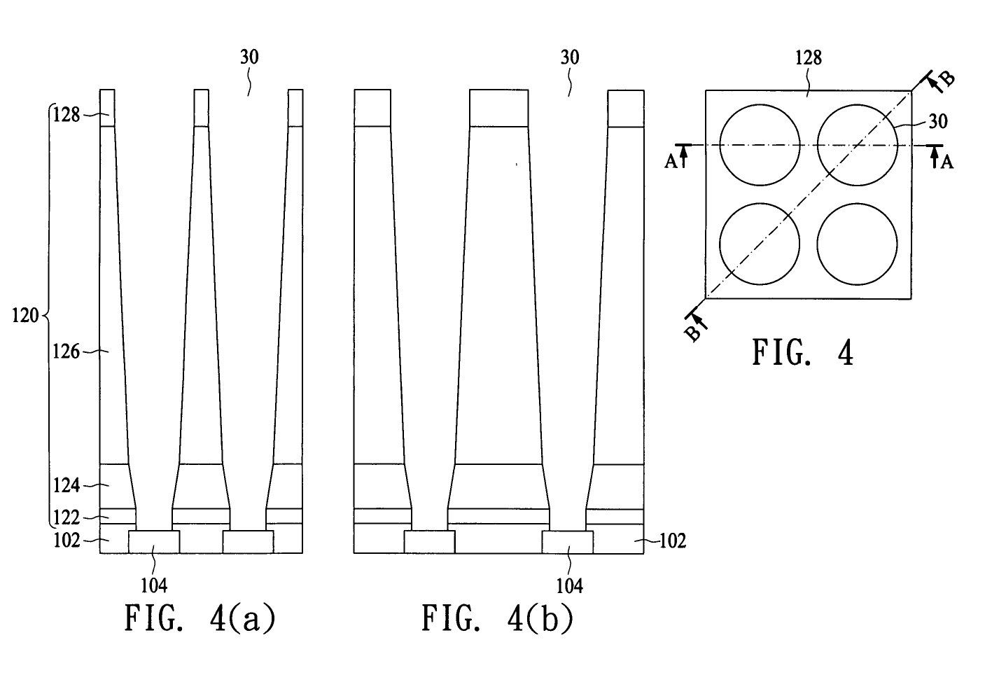

FIG. 3 to FIG. 12 illustrate a method for preparing a capacitor structure 100 of a semiconductor memory according to the first embodiment of the present invention, wherein FIG. 3(a) and FIG. 3(b) are cross-sectional diagrams along the cross-sectional lines A-A and B-B in FIG. 3, and the same for FIG. 4 to FIG. 12. A stack structure 120 is formed on a dielectric layer 102 having a contact plug 104, and lithographic and etching processes are performed to form a plurality of circular openings 30 in the stack structure 120, wherein the circular openings 30 expose the contact plug 104. The stack structure 120 comprises a silicon nitride layer 122, a silicon oxide layer 124 positioned on the silicon nitride layer 122, a silicon oxide layer 126 positioned on the silicon oxide layer 124, and a silicon nitride layer 128 positioned on the silicon oxide layer 126. The silicon oxide layer 124 can be made of borophosphosilicate glass (BPSG), while the silicon oxide layer 126 can be made of tetraethyl orthosilicate (TEOS).

Referring to FIG. 4, FIG. 4(a) and FIG. 4(b), an etchant including phosphoric acid is used to perform an isotropic wet etching process to remove a portion of the silicon nitride layers 122 and 128 from the inner sidewall of the circular opening 30, and another etchant including hydrofluoric acid is used to performed another isotropic wet etching process to remove a portion of the silicon oxide layers 124 and 126 and the dielectric 102. Consequently, the size of the circular opening 30 is enlarged to increase the exposed area of the contract plug 104, which can decrease the contact resistance of the contact plug 104 and increase the surface of the subsequently formed capacitor.

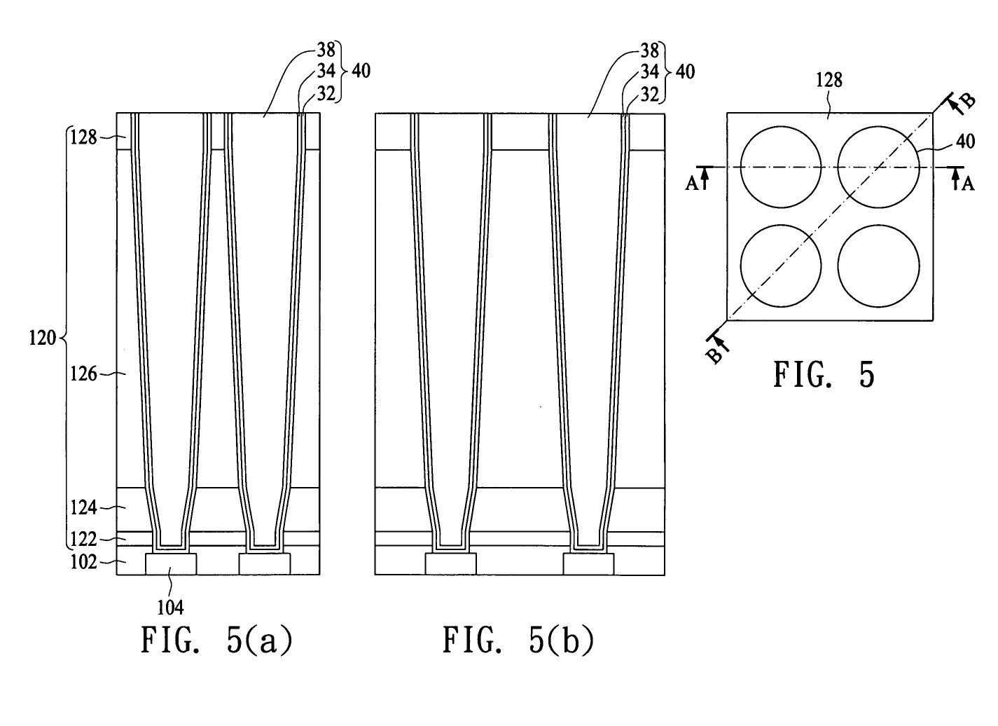

Referring to FIG. 5, FIG. 5(a) and FIG. 5(b), a deposition process such as the atomic layer deposition process is performed to form a titanium nitride layer 32 and a ruthenium layer 34 on the inner sidewall of the circular opening 30 and the surface of the silicon nitride layer 128, and another deposition process is then performed to form a dielectric layer 38 filling the circular opening 30. Subsequently, a planarization process such as the chemical mechanical polish process is performed to remove a portion of the titanium nitride layer 32, the ruthenium layer 34 and the dielectric layer 38 from the surface of the silicon nitride layer 128 such that the titanium nitride layer 32, the ruthenium layer 34 and the dielectric layer 38 remaining in the circular opening 30 form a solid cylinder 40.

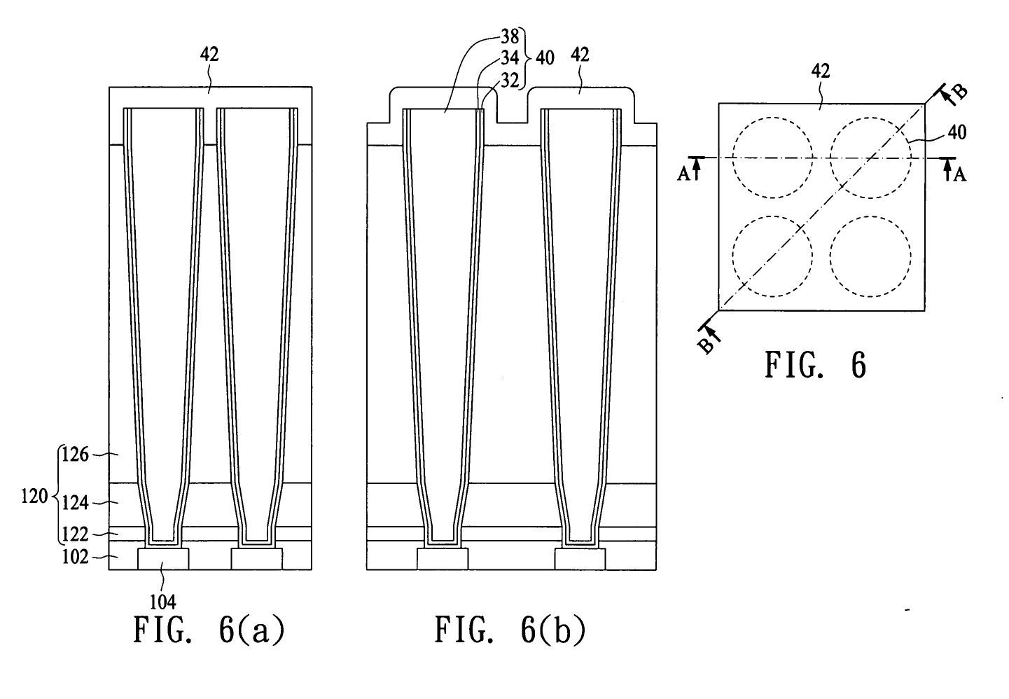

Referring to FIG. 6, FIG. 6(a) and FIG. 6(b), an etchant including phosphoric acid is used to perform an isotropic wet etching process to remove the silicon nitride layer 128 from the surface of the silicon oxide layer 126, i.e., to remove a predetermined portion of the stack structure 120 such that the top end of the solid cylinder 40 is higher than the top end of the stack structure 120. Subsequently, a deposition process is performed to form a mask layer 42 on the surface of the stack structure 120 (the surface of the silicon oxide layer 126) and on the-surface of the solid cylinder 40. The mask layer 42 can be made of silicon oxide or polysilicon. Particularly, the space between the two solid cylinders 40 in FIG. 6(b) is larger than that in FIG. 6(a), i.e., the space between the solid cylinders 40 is not uniform, such that the surface of the mask layer 42 in FIG. 6(b) is not uniform, while the surface of the mask layer 42 in FIG. 6(a) is uniform.

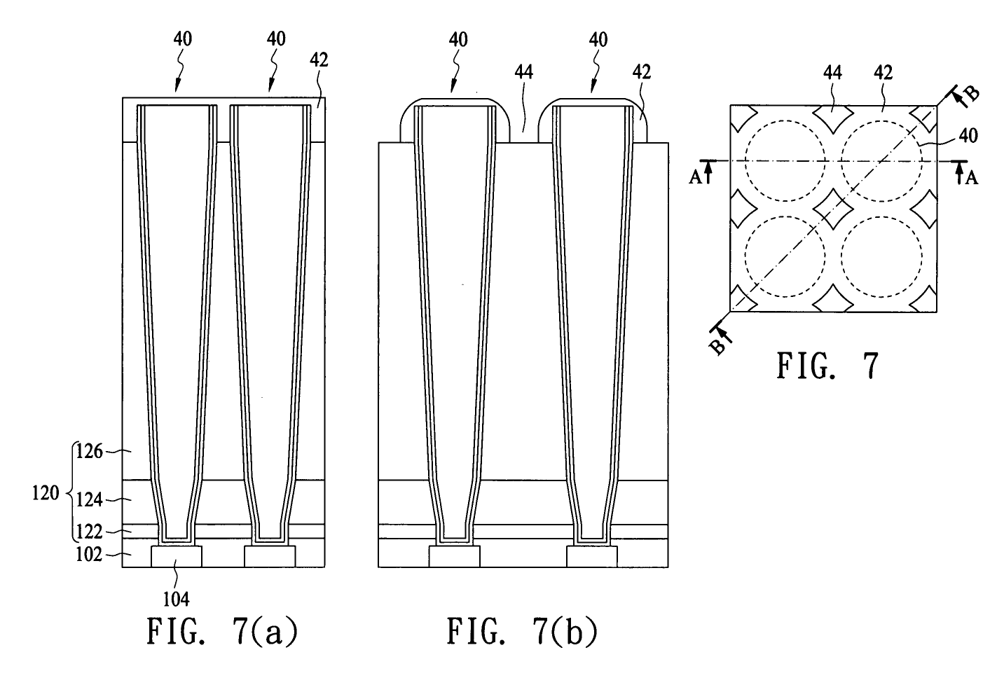

Referring to FIG. 7, FIG. 7(a) and FIG. 7(b), an anisotropic etching process is performed to remove a portion of the mask layer 42 from the surface of the stack structure 120 and the surface of the solid cylinder 40. The anisotropic etching process uniformly decreases the height of the mask layer 42 in FIG. 7(a) since the surface of the mask layer 42 in FIG. 6(a) is uniform. In contrast, the anisotropic etching process can remove a portion of the mask layer 42 from the surface of the stack structure 120 between the two solid cylinders 40 since the surface of the mask layer 42 in FIG. 6(b) is not uniform. Consequently, an opening 44 exposing the stack structure 120 is formed between the two solid cylinders 40, as shown in FIG. 7(b).

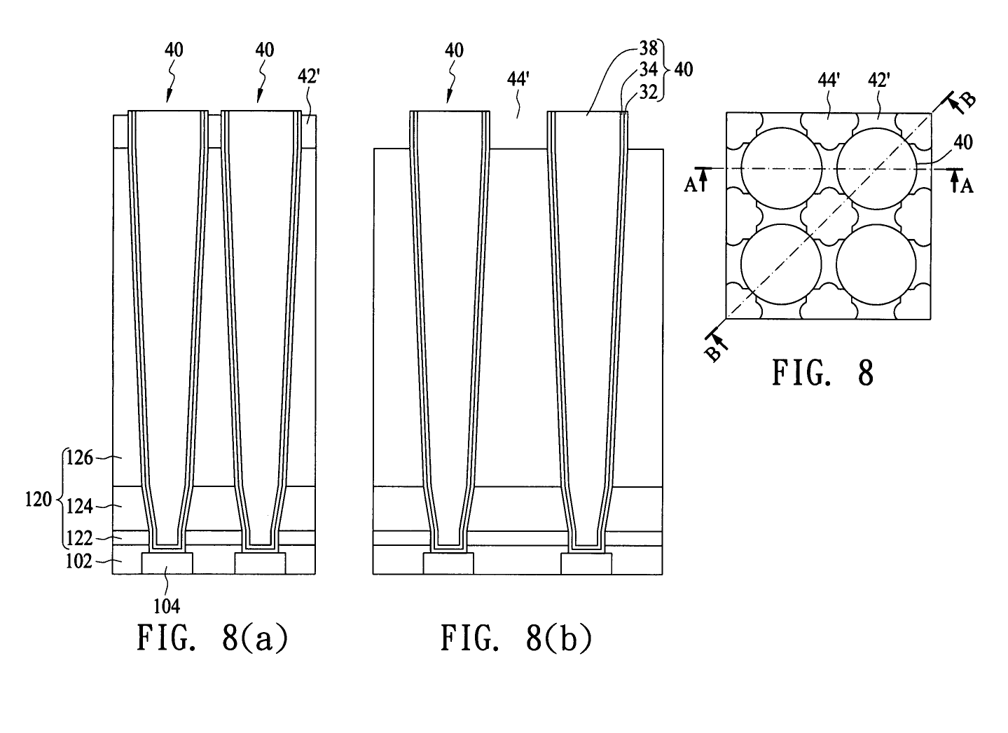

Referring to FIG. 8, FIG. 8(a) and FIG. 8(b), an isotropic wet etching process is performed to remove a portion of the mask layer 42 to enlarge the size of the opening 44. Since the opening 44 exposing the stack structure 120 is positioned between the solid cylinders 40, the etchant of the wet etching process can remove the mask layer 42 from the surface of stack structure 120 between the two cylinders 40 through the opening 44, such that a hard mask 42′ having a plurality of openings 44′ is formed on the stack structure 120. Particularly, the opening 44′ exposes a portion of the stack structure 120 and a portion of the outer sidewall of the solid cylinders 40. If the mask layer 42 is made of polysilicon, potassium hydroxide can be used as the etchant to perform the wet etching process at 80° C. If the mask layer 42 is made of silicon oxide, buffered hydrofluoric acid can be used as the etchant of the wet etching process.

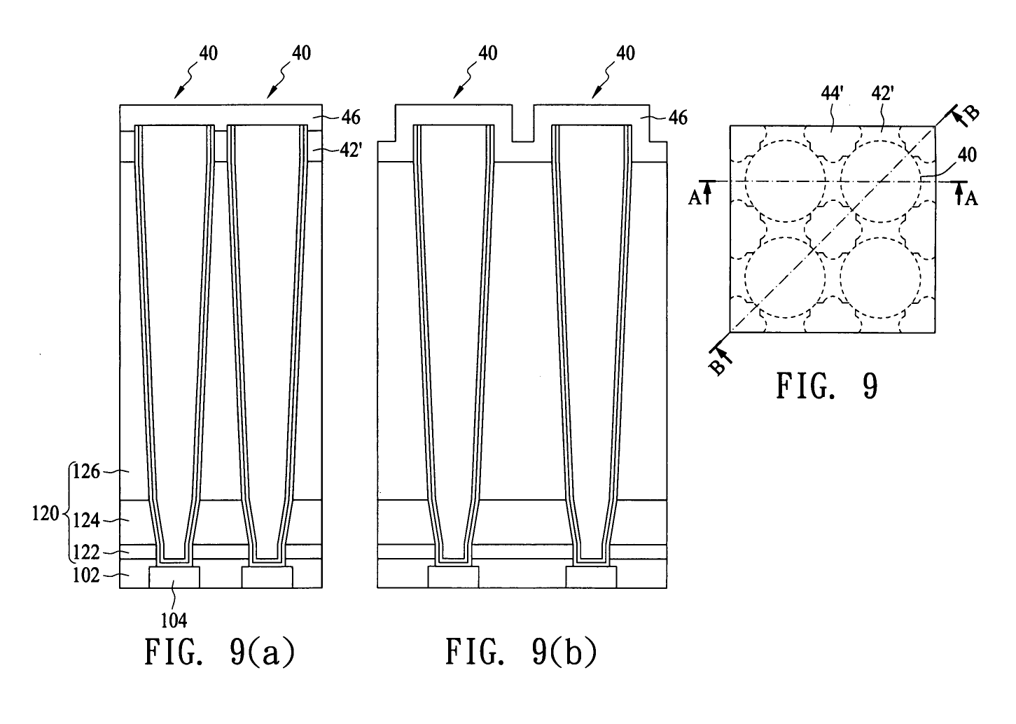

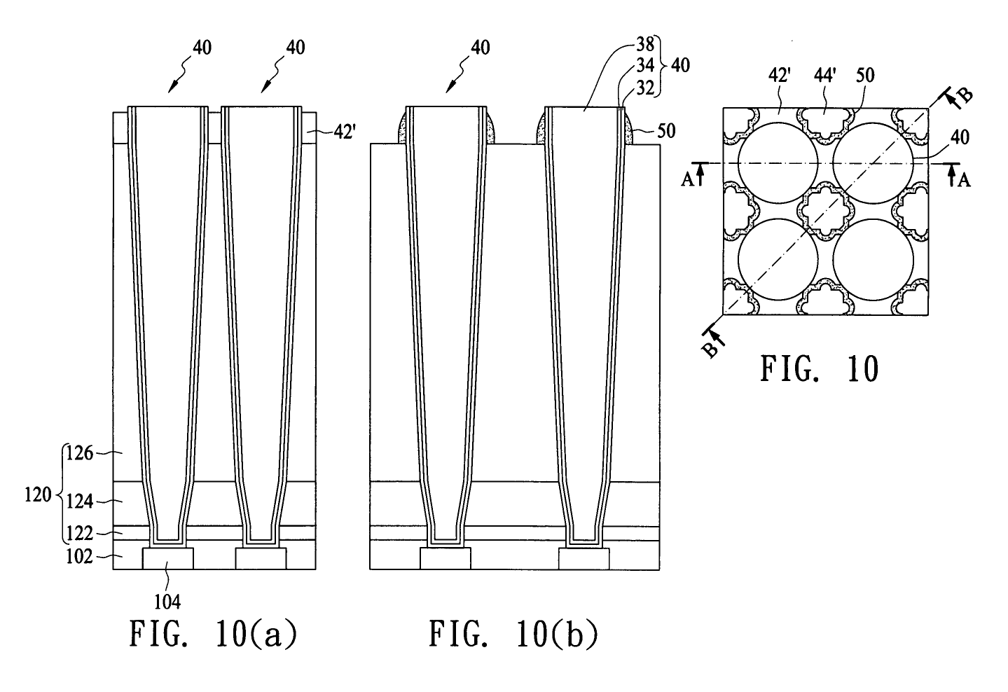

Referring to FIG. 9, FIG. 9(a) and FIG. 9(b), a deposition process is performed to form a supporting layer 46 covering the stack structure 120, the solid cylinders 40 and the hard mask 42′, and the supporting layer 46 can be made of silicon nitride or aluminum oxide. An anisotropic etching process is performed to remove a portion of the supporting layer 46, while the remaining portion of the supporting layer 42 in the opening 44′ forms a plurality of disconnected supporting rings 50, as shown in FIG. 10, FIG. 10(a) and FIG. 10(b). Particularly, each supporting ring 50 is positioned between the solid cylinders 40 and connects a portion of the outer sidewall of the solid cylinders 40, and the hard mask 42′ between the solid cylinders 40 isolates the supporting rings 50 from each other.

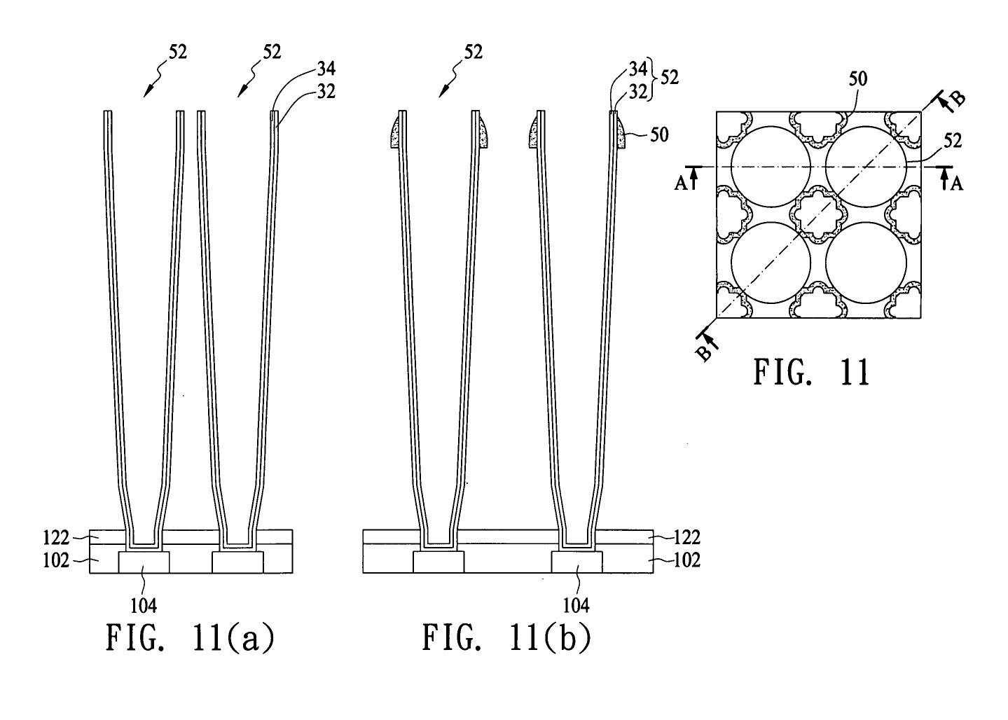

Referring to FIG. 11, FIG. 11(a) and FIG. 11(b), a wet etching process is performed to remove the hard mask 42′, the silicon oxide layer 126, the silicon oxide layer 124 and the dielectric layer 38 to form a plurality of hollow cylinders 52 including the titanium nitride layer 32 and the ruthenium layer 34. The supporting ring 50 is positioned between the hollow cylinders 52 and connects a portion of the outer sidewall of four hollow cylinders 52. Particularly, the supporting ring 50 connects an upper portion of the solid cylinders 40.

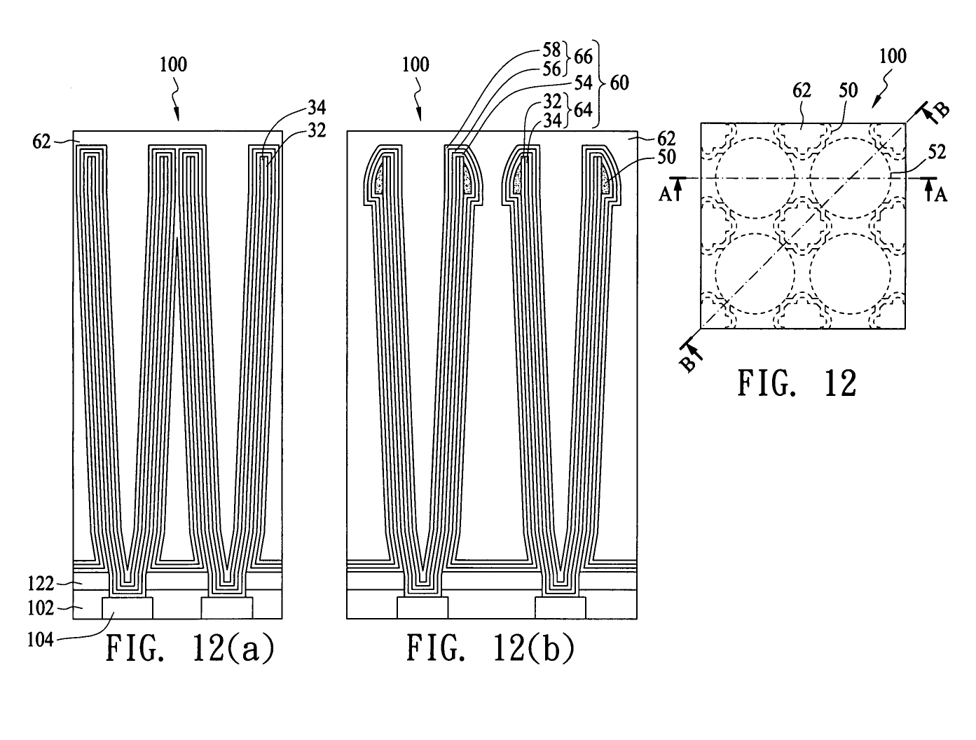

Referring to FIG. 12, FIG. 12(a) and FIG. 12(b), a deposition process such as the atomic layer deposition process is performed to form a dielectric layer made of high-k material on the surface of the hollow cylinder 52, a ruthenium layer 56 on the surface of the dielectric layer 54, and a titanium nitride layer 58 on the surface of the ruthenium layer 56. The high-k material can be aluminum oxide (Al₂O₃), hafnium oxide (HfO₂), titanium oxide (TiO₂), zirconium oxide (ZrO₂), barium titanate (BaTiO₃), strontium titanate (SrTiO₃), or barium strontium titanate (BaSrTiO₃). Particularly, the dielectric layer 54 covers the supporting ring 50 and the inner sidewall and the outer sidewall of the hollow cylinder 52. The titanium nitride layer 32 and the ruthenium layer 34 form a bottom electrode 64, the titanium nitride layer 58 and the ruthenium layer 56 form a top electrode 66, and the bottom electrode 64, the dielectric layer 54 and the top electrode 66 form a capacitor 60. Subsequently, a spin-coating process is performed to form a dielectric layer 62 covering the capacitor 60 to complete the capacitor structure 100.

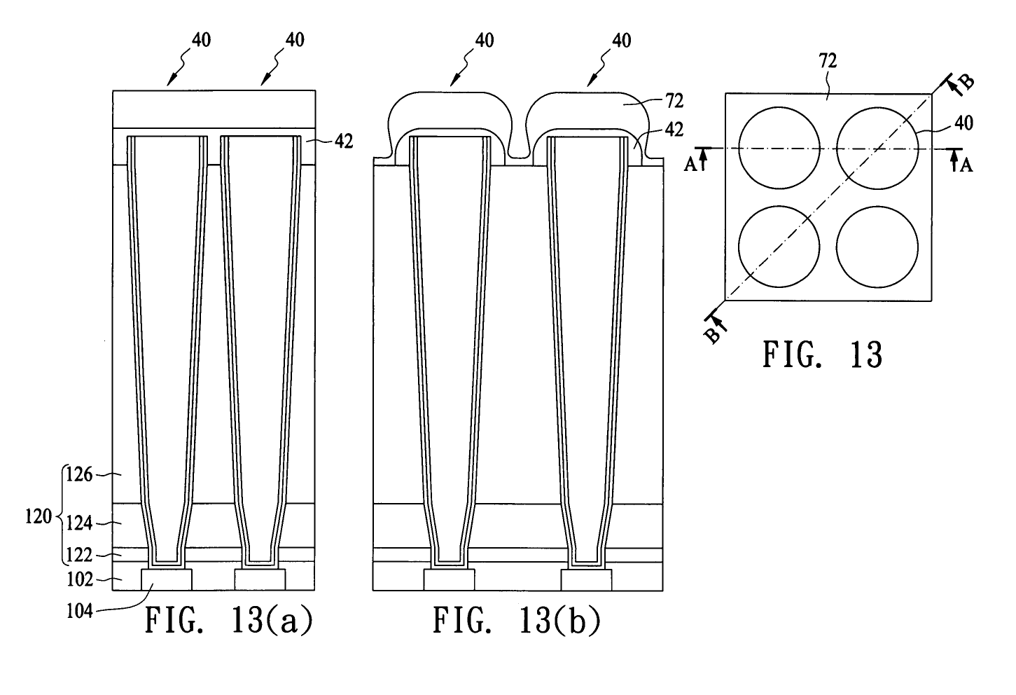

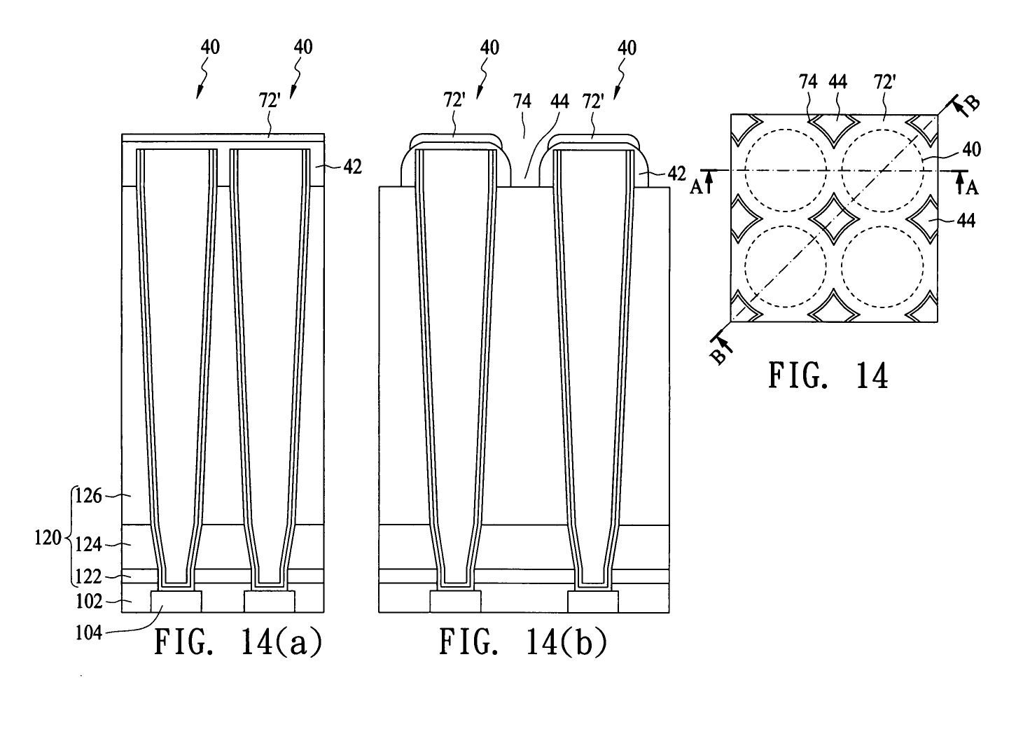

FIG. 13 to FIG. 18 illustrate a method for preparing a capacitor structure 70 of a semiconductor memory according to the second embodiment of the present invention, wherein FIG. 13(a) and FIG. 13(b) are cross-sectional diagrams along the cross-sectional lines A-A and B-B in FIG. 13, and the same for FIG. 14 to FIG. 18. The fabrication processes shown in FIG. 3 to FIG. 7 are performed, and a physical vapor deposition process is then performed to form a metal layer 72 on the surface of the mask layer 42 and on the surface of the stack structure 120. The metal layer 72 can be made of titanium nitride, titanium or aluminum. Since the step coverage ability of the physical vapor deposition process is poor and the height of the mask layer 42 is not uniform, i.e., there is a step profile, as shown in FIG. 13(b), the thickness of the metal layer 72 on the solid cylinders 40 is higher than that on the stack structure 120.

Referring to FIG. 14, FIG. 14(a) and FIG. 14(b), an anisotropic dry etching process is performed to remove a portion of the metal layer 72 from the surface of the stack structure 120 between the solid cylinders 40 to form a mask layer 72′ having an opening 74 on the mask layer 42, wherein the etching gas of the dry etching process can be carbon tetrafluoride, chlorine or chlorine/(trifluoromethane). The anisotropic dry etching process uniformly decreases the height of the mask layer 72 in FIG. 14(a) since the surface of the mask layer 72 is uniform in FIG. 13(a). In contrast, the anisotropic dry etching process can remove a portion of the mask layer 72 from the surface of the stack structure 120 between the two solid cylinders 40 since the surface of the mask layer 42 is not uniform, i.e., there is a step profile, in FIG. 13(b). Consequently, the remaining portion of the metal layer 72 on the solid cylinders 40 forms the mask layer 72′, and the opening 74 in the mask layer 72′ exposes a portion of the stack structure 120, as shown in FIG. 14(b). Particularly, the opening 74 of the mask layer 72′ also exposes a portion of the mask layer 42.

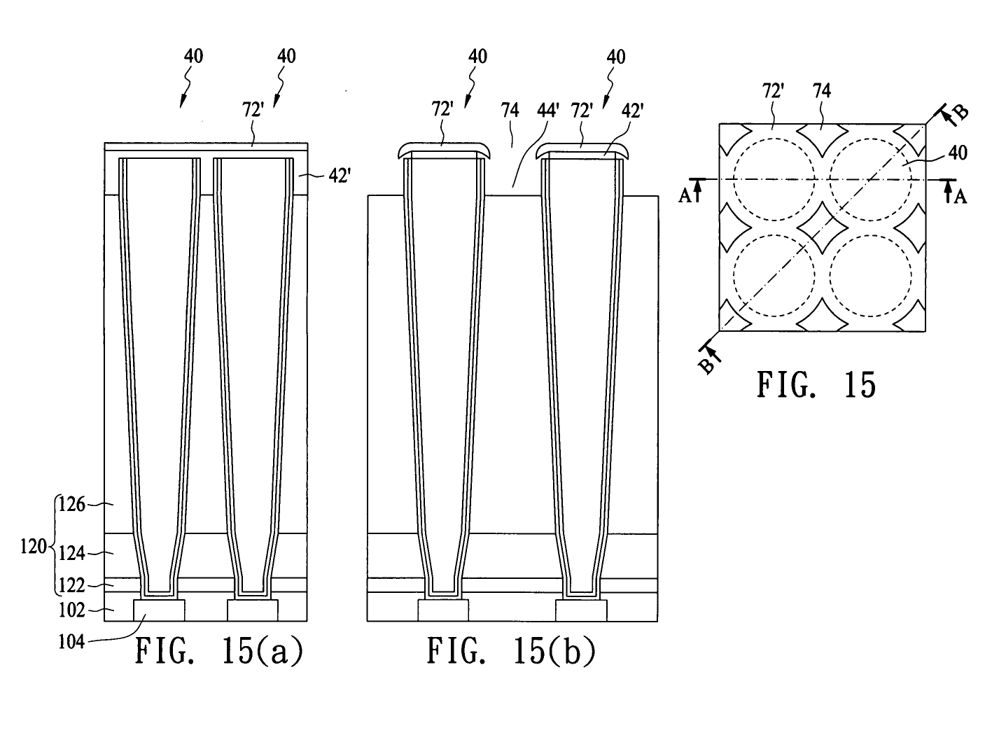

Referring to FIG. 15, FIG. 15(a) and FIG. 15(b), an isotropic wet etching process is performed to remove a portion of the mask layer 42 to a hard mask 42′ having a plurality of openings 44′ on the stack structure 120. Since the mask layer 72′ has an opening 74 exposing the stack structure 120 between the solid cylinders 40, the etchant of the wet etching process can remove the mask layer 42 from the surface of the stack structure 120 between the solid cylinders 40 through the opening 74, such that the size of the opening 44 is enlarged to be in contact with the outer sidewall of the solid cylinders 40 to form the hard mask 42′. Particularly, the opening 44′ exposes a portion of the stack structure 120 and a portion of the outer sidewall of the solid cylinders 40.

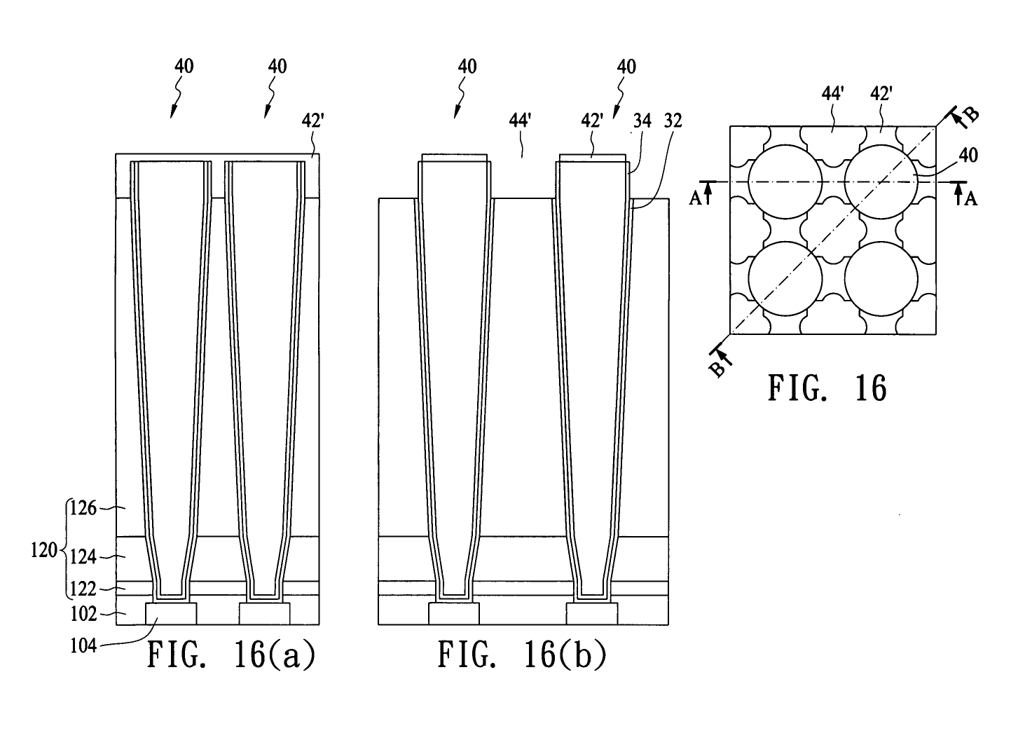

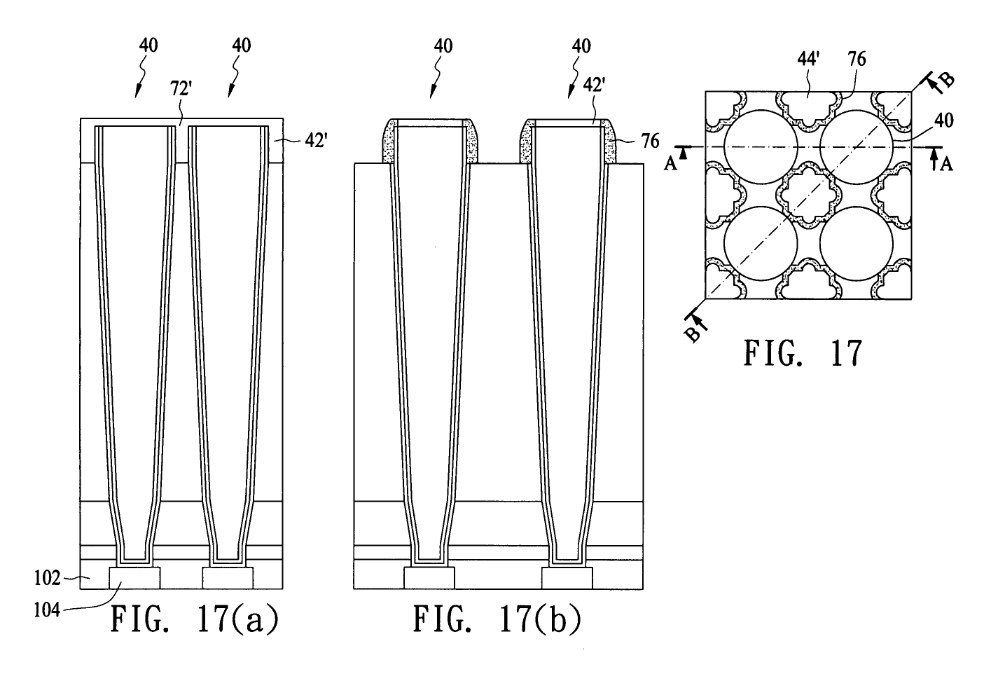

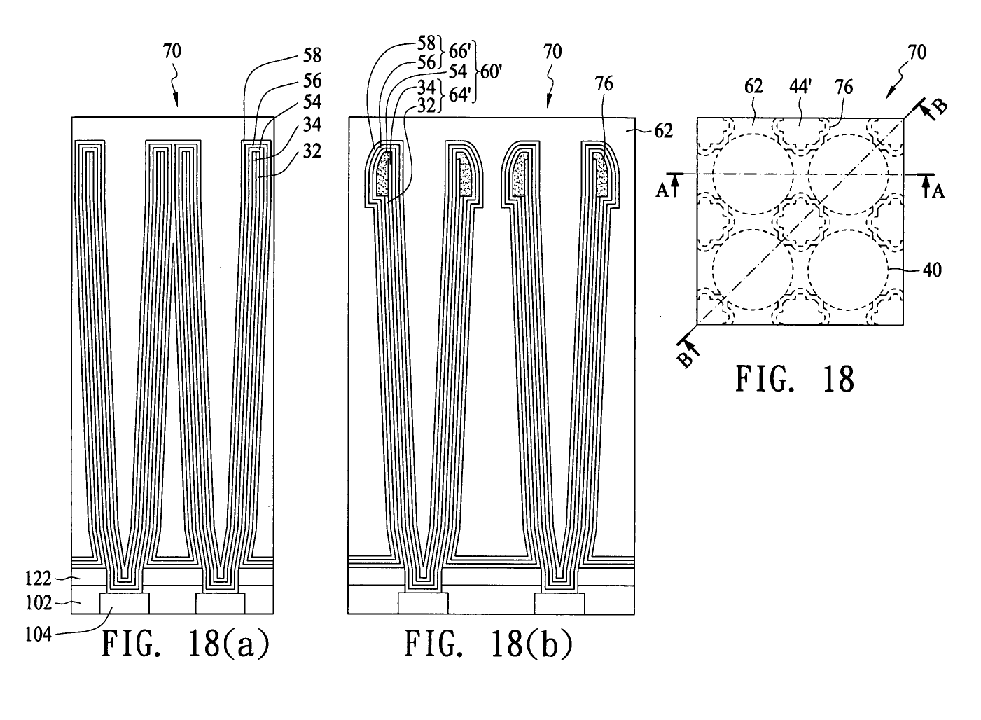

Referring to FIG. 16, FIG. 16(a) and FIG. 16(b), an etchant including ceric ammonium nitrate and acetic acid is used to perform a wet etching process to completely remove the mask layer 72′ and a portion of the titanium nitride layer 32 from the outer sidewall of the solid cylinders 40 above the stack structure 120. The fabrication processes shown in FIG. 9 and FIG. 10 are performed to form a plurality of supporting rings 76 in the opening 44′, as shown in FIG. 17, FIG. 17(a) and FIG. 17(b). Subsequently, the fabrication processes shown in FIG. 11 and FIG. 12 are performed to complete the capacitor structure 70, as shown in FIG. 18, FIG. 18(a) and FIG. 18(b). The titanium nitride layer 32 and the ruthenium layer 34 together serve as a bottom electrode 64′, the ruthenium layer 56 and the titanium nitride layer 58 serve as a top electrode 66′, and the bottom electrode 64′, the dielectric layer 54 and the top electrode 66′ form a capacitor 60′.

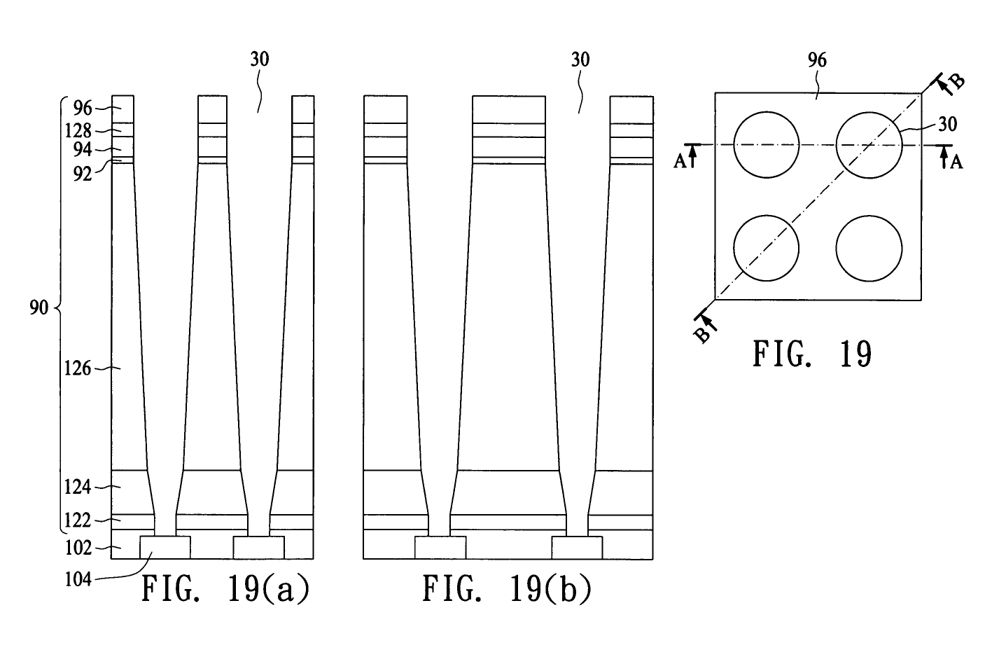

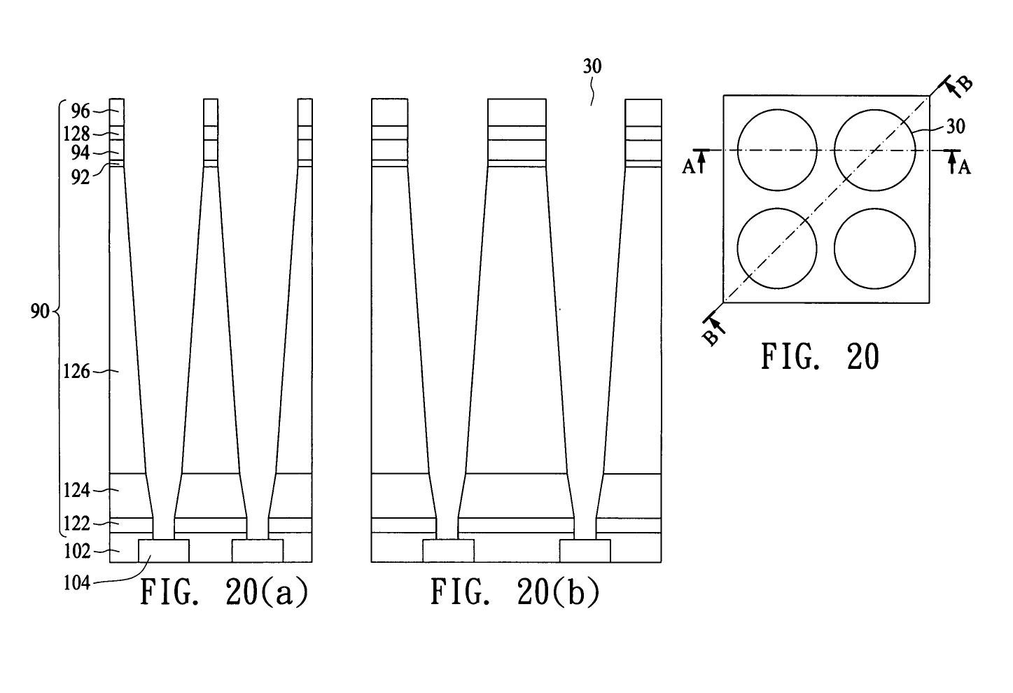

FIG. 19 to FIG. 26 illustrate a method for preparing a capacitor structure 80 of a semiconductor memory according to the third embodiment of the present invention, wherein FIG. 19(a) and FIG. 19(b) are cross-sectional diagrams along the cross-sectional lines A-A and B-B in FIG. 19, and the same for FIG. 20 to FIG. 26. A stack structure 90 is formed on a dielectric layer 102 having a contact plug 104, and lithographic and etching processes are performed to a plurality of circular openings 30 in the stack structure 90, wherein the circular openings 30 expose the contact plug 104. The stack structure 90 comprises a silicon nitride layer 122, a silicon oxide layer 124, a silicon oxide layer 126, a polysilicon layer 92, a silicon oxide layer 94, a silicon nitride layer 128 and a polysilicon layer 96 positioned on the dielectric layer 102 in sequence.

Referring to FIG. 20, FIG. 20(a) and FIG. 20(b), an etchant including potassium hydroxide is used to perform an isotropic wet etching process to remove a portion of the polysilicon layer 92 and the polysilicon layer 96 from the inner sidewall of the circular openings 30, and another etchant including hydrofluoric acid is used to perform another isotropic wet etching process to remove a portion of the silicon oxide layer 94, the silicon oxide layer 124, the silicon oxide layer 126 and the dielectric 102. Consequently, the size of the circular opening 30 is enlarged to increase the exposed area of the contract plug 104, which can decrease the contact resistance of the contact plug 104 and increase the surface of the subsequently formed capacitor.

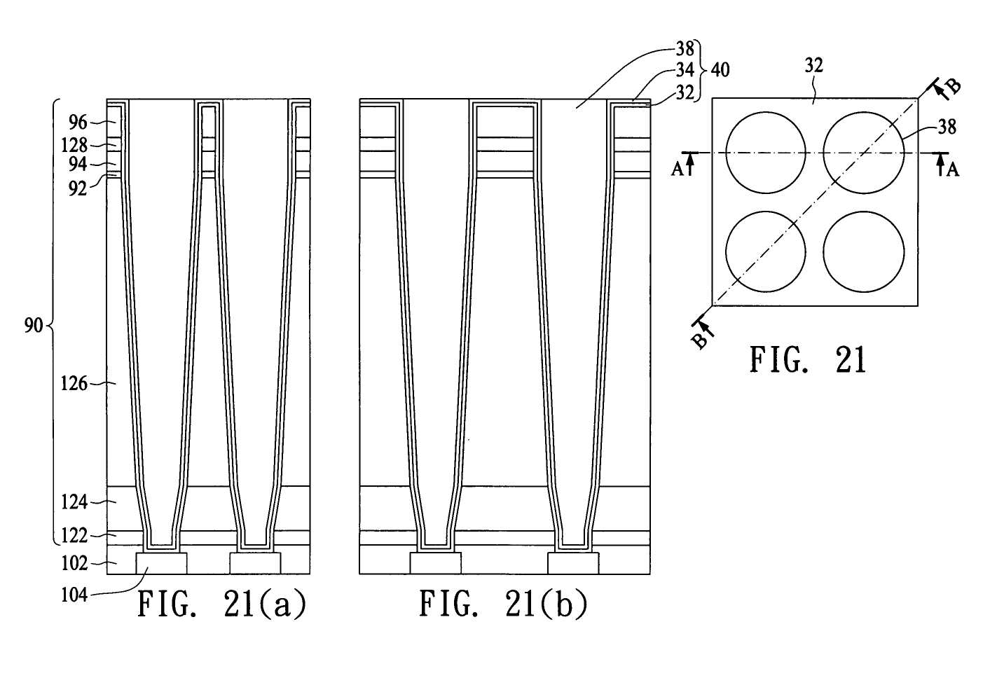

Referring to FIG. 21, FIG. 21(a) and FIG. 21(b), a deposition process such as the atomic layer deposition process is performed to form a titanium nitride layer 32 and a ruthenium layer 34 on the inner sidewall of the circular opening 30 and the surface of the polysilicon layer 96, and another deposition process is then performed to form a dielectric layer 38 filling the circular opening 30. Subsequently, a planarization process such as the chemical mechanical polish process is performed to remove a portion of the dielectric layer 38 from the surface of the ruthenium layer 34 such that the titanium nitride layer 32, the ruthenium layer 34 and the dielectric layer 38 in the circular opening 30 form a solid cylinder 40.

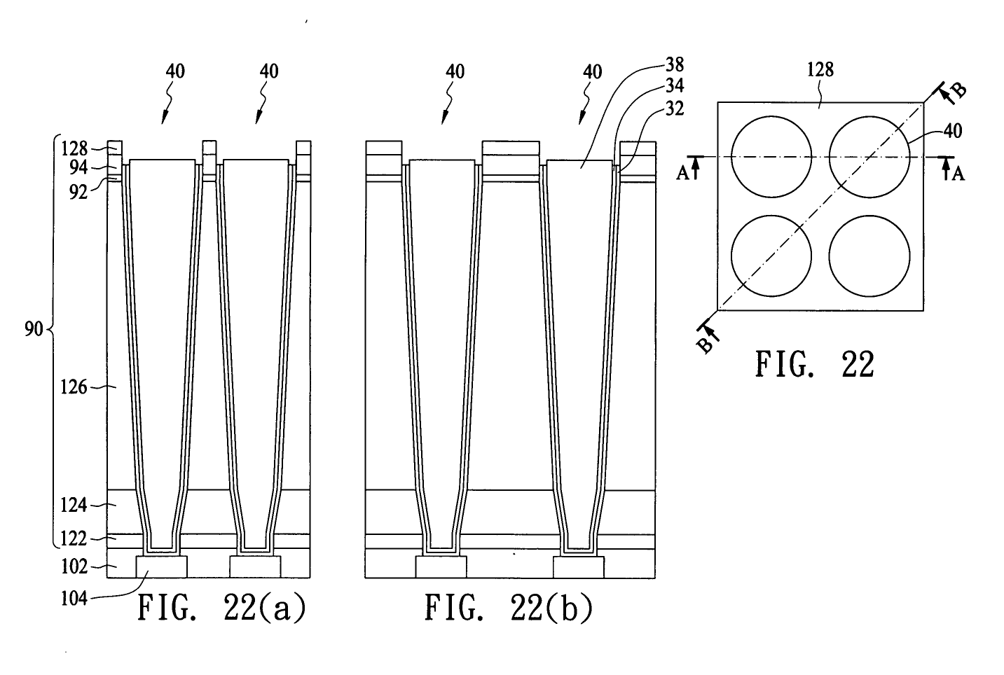

Referring to FIG. 22, FIG. 22(a) and FIG. 22(b), an anisotropic dry etching process is performed to remove a portion of the dielectric layer 38, and an etchant including ceric ammonium nitrate and acetic acid is used to perform a wet etching process to remove a portion of the titanium nitride layer 32 and the ruthenium layer 34 such that the top ends of the titanium nitride layer 32 and the ruthenium layer 34 are lower than the top end of the dielectric layer 38. Subsequently, an etchant including potassium hydroxide is used to perform an isotropic wet etching process to completely remove the polysilicon layer 96 from the surface of the silicon nitride layer 128.

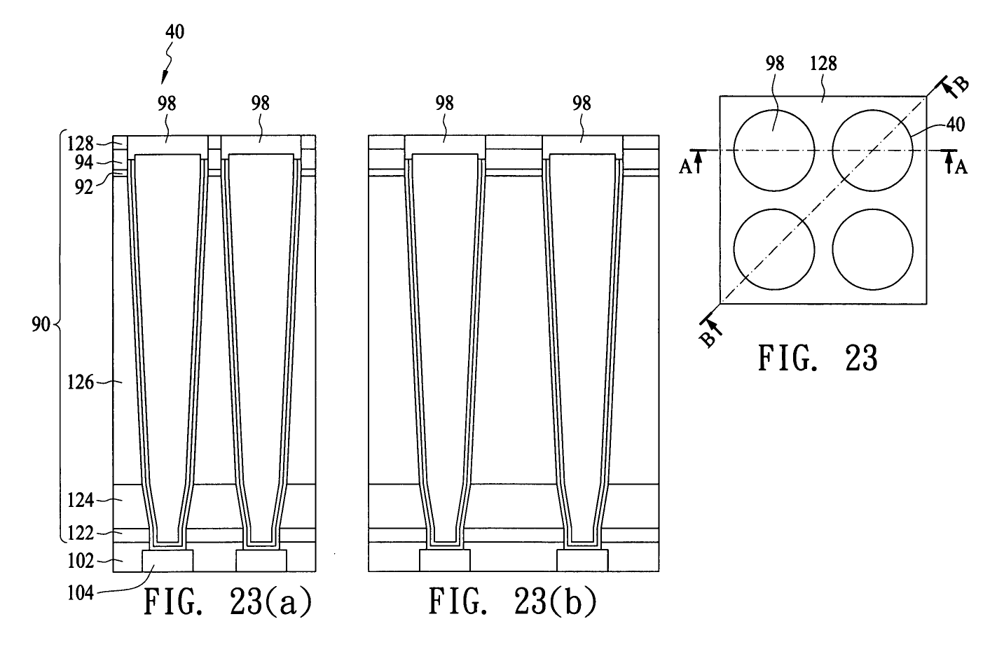

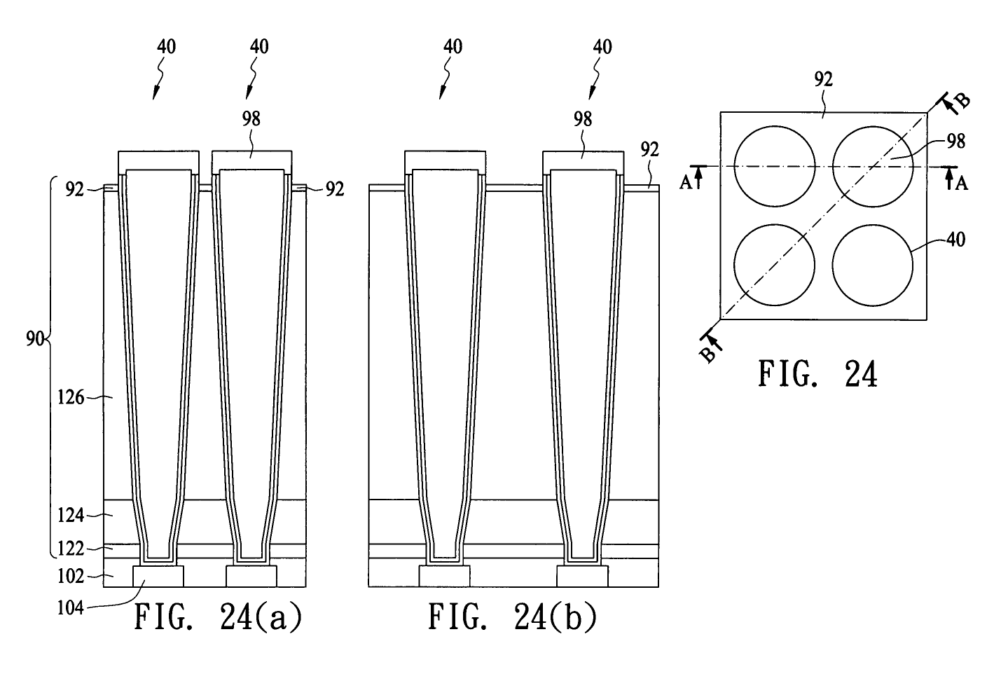

Referring to FIG. 23, FIG. 23(a) and FIG. 23(b), a deposition process is performed to form a mask layer 98 covering the silicon nitride layer 128, the titanium nitride layer 32, the ruthenium layer 34 and the dielectric layer 38, and a planarization process such as the chemical mechanical polish process is performed to remove a portion of the mask layer 98 from the surface of the silicon nitride layer 128. Subsequently, an etchant including phosphoric acid is used to perform an isotropic wet etching process to completely remove the silicon nitride layer 128 from the surface of the silicon oxide layer 94, and the silicon oxide layer 94 from the surface of the polysilicon layer 92, i.e., remove a portion of the stack structure 90 such that the top end of the solid cylinders 40 including the titanium nitride layer 32, the ruthenium layer 34 and the dielectric layer 38 is higher than the top end of the stack structure 90, as shown in FIG. 24, FIG. 24(a) and FIG. 24(b).

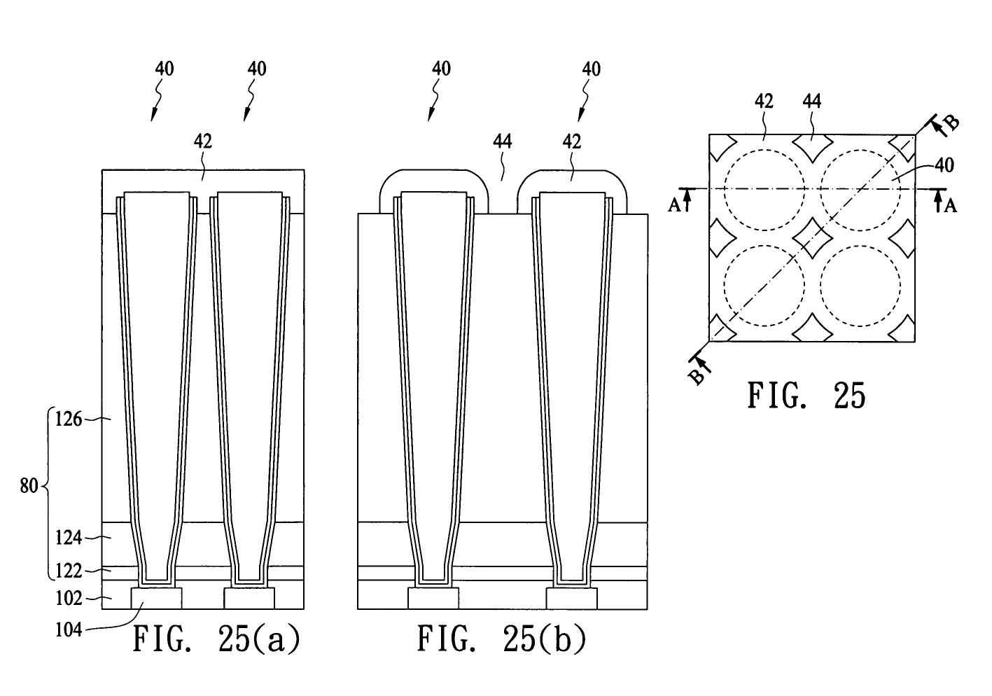

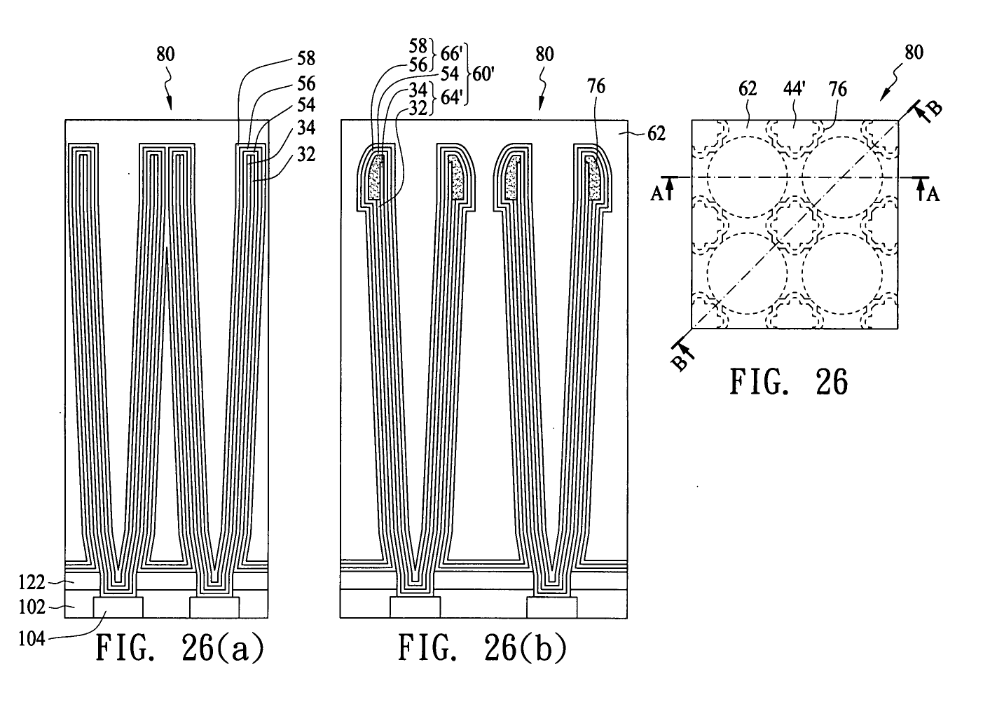

Referring to FIG. 25, FIG. 25(a) and FIG. 25(b), a deposition process is performed to form a mask layer 42 on the surface of the stack structure 90, i.e., the surface of the polysilicon layer 92, and on the surface of the solid cylinders 40, wherein the mask layer 42 can be made of polysilicon or silicon oxide. Subsequently, an anisotropic dry etching process is performed to remove a portion of the mask layer 42 from the surface of the stack structure 90 and the surface of the solid cylinders 40 to form an opening 40 exposing the stack structure 90 between the solid cylinders 40. The fabrication processes shown in FIG. 13 to FIG. 18 are then performed to complete the capacitor structure 80, as shown in FIG. 26, FIG. 26(a) and FIG. 26(b).

The conventional hollow semicrown-shaped bottom electrode 20′ is likely to lean or even collapse due to insufficient mechanical supporting strength during the fabrication process. In contrast, the capacitor structure 100, 70 and 80 of the present invention possesses the supporting ring 50 and 76 positioned between the hollow cylinders 52 and connecting a portion of the outer sidewall of the hollow cylinders 52 such that the hollow cylinders 52 provide mechanical support to each other through the connection of the supporting rings 50 and 76. Consequently, the capacitor structure 100, 70 and 80 will not lean or collapse during the subsequent fabrication process, and the method of the present invention is suitable for application to the high integrity fabrication process.

The above-described embodiments of the present invention are intended to be illustrative only. Numerous alternative embodiments may be devised by those skilled in the art without departing from the scope of the following claims.

What is claimed is:

1. A capacitor structure of a semiconductor memory, comprising:
a plurality of cylinders each having an outer sidewall; and
at least one supporting ring positioned between the cylinders and connecting portions of the outer sidewalls of the cylinders.

2. The capacitor structure of a semiconductor memory of claim 1, wherein the supporting ring connects upper portions of the cylinders.

3. The capacitor structure of a semiconductor memory of claim 1, wherein the cylinders are hollow cylinders.

4. The capacitor structure of a semiconductor memory of claim 3, wherein each hollow cylinder includes a first electrode of the capacitor structure.

5. The capacitor structure of a semiconductor memory of claim 4, further comprising:
a dielectric layer positioned on a surface of the first electrode; and
a second electrode positioned on a surface of the dielectric layer.

6. The capacitor structure of a semiconductor memory of claim 5, wherein the dielectric layer covers an inner sidewall and the outer sidewall of the hollow cylinder and the supporting ring.

7. The capacitor structure of a semiconductor memory of claim 5, wherein the dielectric layer includes aluminum oxide, hafnium oxide, titanium oxide, zirconium oxide, barium titanate, strontium titanate, or barium strontium titanate.

8. The capacitor structure of a semiconductor memory of claim 1, wherein the supporting ring includes aluminum oxide or silicon nitride.

9. The capacitor structure of a semiconductor memory of claim 1, comprising a plurality of disconnected supporting rings.

10. The capacitor structure of a semiconductor memory of claim 9, further comprising a hard mask isolating the supporting rings.

11. The capacitor structure of a semiconductor memory of claim 10, wherein the hard mask includes silicon oxide or polysilicon.

12. A method for preparing a capacitor structure of a semiconductor memory, comprising the steps of:
forming a plurality of solid cylinders in a stack structure, each solid cylinder having a top end higher than a top end of the stack structure;
forming a hard mask having a plurality of first openings on the stack structure, each first opening exposing a portion of the stack structure and a portion of an outer sidewall of the solid cylinder; and
forming a supporting ring in the first opening of the hard mask, the supporting ring connecting portions of the outer sidewalls of the solid cylinders.

13. The method for preparing a capacitor structure of a semiconductor memory of claim 12, wherein the supporting ring includes aluminum oxide or silicon nitride, and the hard mask includes silicon oxide or polysilicon.

14. The method for preparing a capacitor structure of a semiconductor memory of claim 12, wherein the step of forming a supporting ring in the first opening of the hard mask comprises:
forming a supporting layer covering the stack structure, the solid cylinders and the hard mask; and
performing an anisotropic etching process to remove a portion of the supporting layer such that the supporting layer remaining in the first opening forms the supporting ring.

15. The method for preparing a capacitor structure of a semiconductor memory of claim 12, wherein the step of forming a hard mask having a plurality of first openings on the stack structure comprises:
forming a mask layer on the stack structure and the solid cylinders;
performing an anisotropic etching process to remove a portion of the mask layer from the stack structure to form a second opening exposing the stack structure; and
performing an isotropic etching process to remove a portion of the mask layer from the stack structure to enlarge the second opening to be in contact with the outer sidewall of the solid cylinders so as to form the hard mask.

16. The method for preparing a capacitor structure of a semiconductor memory of claim 12, wherein the step of forming a hard mask having a plurality of first openings on the stack structure comprises:
forming a first mask layer on a surface of the stack structure and a surface of the solid cylinders;
forming a second mask layer having a second opening on the first mask layer, the second opening exposing a portion of the first mask layer;
performing an isotropic etching process to remove a portion of the first mask layer to enlarge the second opening to be in contact with the outer sidewall of the solid cylinders; and
removing the second mask layer such that the first mask layer forms the hard mask.

17. The method for preparing a capacitor structure of a semiconductor memory of claim 16, wherein the step of forming a second mask layer having a second opening on the first mask layer comprises:
performing a physical vapor deposition process to form a metal layer on a surface of the first mask layer and the surface of the stack structure; and
performing an anisotropic etching process to remove a portion of the metal layer from the surface of the stack structure to form the second opening in the metal layer.

18. The method for preparing a capacitor structure of a semiconductor memory of claim 12, wherein the step of forming a plurality of solid cylinders in a stack structure comprises:
forming an opening in the stack structure;
forming at least one conductive layer on an inner sidewall of the opening;
forming a dielectric layer filling the opening; and
removing a predetermined portion of the stack structure such that the top end of the solid cylinder is higher than the top end of the stack structure and the solid cylinder includes the dielectric layer and the conductive layer.

19. The method for preparing a capacitor structure of a semiconductor memory of claim 18, wherein the stack structure includes a silicon oxide layer and a silicon nitride layer positioned on the silicon oxide layer, and the step of removing a predetermined portion of the stack structure is to remove the silicon nitride layer.

20. The method for preparing a capacitor structure of a semiconductor memory of claim 12, wherein the step of forming a plurality of solid cylinders in a stack structure comprises:
forming an opening in the stack structure;
forming at least one conductive layer on an inner sidewall of the opening;
forming a dielectric layer filling the opening;
removing a predetermined portion of the conductive layer and the dielectric layer;
forming a mask layer covering the conductive layer and the dielectric layer; and
removing a predetermined portion of the stack structure such that the top end of the solid cylinder is higher than the top end of the stack structure and the solid cylinder includes the dielectric layer and the conductive layer.

21. The method for preparing a capacitor structure of a semiconductor memory of claim 20, wherein the stack structure includes a polysilicon layer and a silicon oxide layer positioned on the polysilicon layer, and the step of removing a predetermined portion of the stack structure is to remove the silicon oxide layer.
